(19) United States
(12) Patent Application Publication
(10) Pub. No.: US 2003/0155077 A1
(43) Pub. Date: Aug. 21, 2003

(54) Substrate processing apparatus

(75) Inventors: Akihiro Hisai, Kyoto (JP); Tsuyoshi Matsuka, Kyoto (JP); Koji Kaneyama, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/351,648

(22) Filed: Jan. 24, 2003

(30) Foreign Application Priority Data
Feb. 20, 2002 (JP) P2002-043339

(51) Int. Cl. H01L 21/306; C23F 1/00; C23C 16/00

(52) U.S. Cl. 156/345.32; 156/345.31; 118/719

(57) ABSTRACT

A substrate processing apparatus performing prescribed processing on a substrate is provided with a CD measuring unit serving as an inspection unit, an asher unit serving as a regenerative processing unit and a cleaning unit performing cleaning. After the substrate processing apparatus performs resist coating, exposure, development and the like on the substrate and terminates the development, a transport robot transfers the substrate to the CD inspection unit so that the CD inspection unit inspects whether or not the line width of a resist film formed through the development is within the range of a prescribed value. The transport robot transfers a substrate having a line width deviating from the prescribed value to the asher unit so that the asher unit regenerates the substrate by removing the resist film, the cleaning unit cleans the substrate and thereafter the substrate processing apparatus performs prescribed processing again. Thus, a substrate processing apparatus reducing a burden for transferring a defective substrate in the regenerative processing can be provided.

### BACKGROUND OF THE INVENTION

1. Field of the Invention

The present invention relates to a substrate processing apparatus performing processing such as resist coating or thermal processing on a semiconductor substrate, a glass substrate for a liquid crystal display, a glass substrate for a photomask or a substrate for an optical disk (hereinafter simply referred to as “substrate”).

2. Description of the Background Art

In a step of manufacturing a substrate, a substrate processing apparatus such as a coater, an exposer, a developer or a composite apparatus having functions thereof performs processing on the substrate. Generally known is a technique of detecting and selecting a substrate (hereinafter referred to as “defective substrate”) not properly subjected to such processing in a subsequent step. Thus, reliability of the manufactured substrate can be improved.

For example, a technique of mounting a film thickness measuring apparatus in a resist coating system for automatically detecting defective coating is proposed as such a technique. According to this technique, defective substrates requiring reworking are extracted and transferred to a dedicated reworking apparatus such as an ashing apparatus or a resist separator manually or through an AGV or an OHT, to be collectively processed therein and returned to the substrate processing apparatus for reprocessing.

According to the aforementioned technique, however, the several extracted substrates must be transferred between the substrate processing apparatus and the reworking apparatus. In general, the substrate processing apparatus and the reworking apparatus are set in different areas of a factory, and hence transfer of the substrates therebetween results in a heavy processing burden.

Further, lots processed without reworking get sparse in a carrier (cassette), to disadvantageously exert bad influence on subsequent substrate processing or management.

In addition, an interruption lot must be fed to the substrate processing apparatus only for reprocessing after reworking and hence precedent and subsequent lots must disadvantageously be adjusted.

### SUMMARY OF THE INVENTION

The present invention is directed to a technique related to a substrate processing apparatus performing processing such as resist coating or thermal processing on a substrate.

A substrate processing apparatus according to a preferred embodiment of the present invention comprises a plurality of processing units, each executing prescribed processing on a substrate, including a regenerative processing unit regenerating the substrate and a transport mechanism transporting the substrate between the plurality of processing units, while the plurality of processing units and the transport mechanism are integrated with each other.

Thus, regenerative processing can be completed in an integrated apparatus, so that the substrate may not be transferred between areas but the efficiency of the regenerative processing can be improved.

Preferably, the substrate processing apparatus further comprises an inspection unit performing an inspection on the substrate.

Thus, the apparatus can perform the inspection therein with no requirement for a separate inspection step.

Accordingly, a first object of the present invention is to provide a substrate processing apparatus capable of reducing a burden for transferring a defective substrate.

A second object of the present invention is to provide a substrate processing apparatus capable of readily performing lot (substrate) management when causing a defective substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view showing the structure of a substrate processing apparatus according to a first preferred embodiment of the present invention;

FIG. 2 is a side elevational view conceptually showing an asher unit in the substrate processing apparatus according to the first preferred embodiment;

FIG. 3 is a schematic plan view showing the structure of a substrate processing apparatus according to a second preferred embodiment of the present invention;

FIG. 4 is a side elevational view showing the structure of a macro inspection unit in the substrate processing apparatus according to the second preferred embodiment; and

FIG. 5 is a side elevational view showing the structure of a resist separation unit in the substrate processing apparatus according to the second preferred embodiment.

### DESCRIPTION OF THE PREFERRED EMBODIMENTS

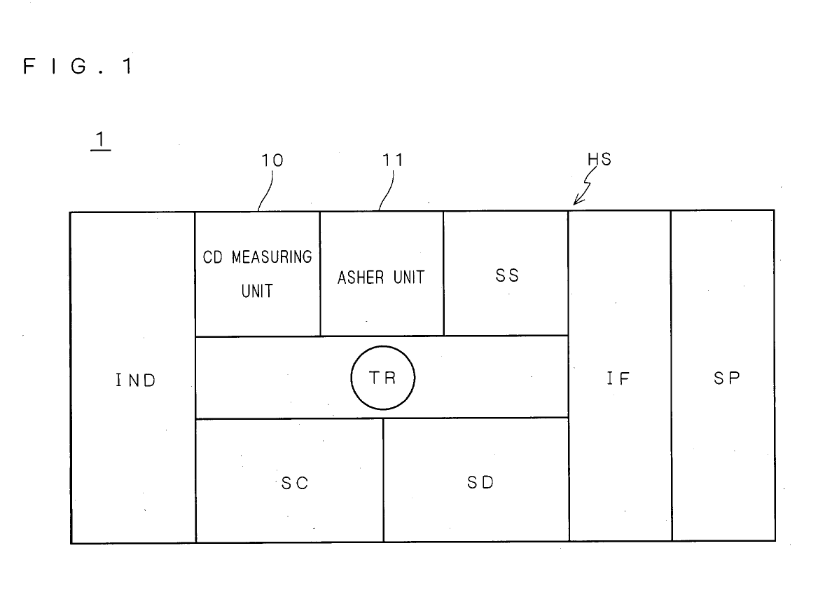

FIG. 1 is a plan view showing the overall structure of a substrate processing apparatus 1 according to a first preferred embodiment of the present invention. This substrate processing apparatus 1 for performing resist coating or development on a substrate 90 is an integrated apparatus comprising an indexer IND introducing/discharging the substrate 90 into/from the substrate processing apparatus 1, a coating unit SC coating the substrate 90 with resist, an exposure unit SP exposing the substrate 90, an interface IF transferring/receiving the substrate 90 to/from an exposure unit SP, a developing unit SD developing the substrate 90, a CD (critical dimension) measuring unit 10 measuring the line width of the substrate 90, an asher unit 11 regenerating the substrate 90, a cleaning unit SS cleaning the substrate 90 and a transport robot TR.

The indexer IND, mounted with a carrier (not shown) capable of storing a plurality of substrates 90, delivers an unprocessed substrate 90 from the carrier to the transport robot TR while receiving a processed substrate 90 from the transport robot TR and storing the same in the carrier. The carrier may be an OC (open cassette) exposing the stored substrates 90 to the open air, an FOUP (front opening unified pod) storing the substrates 90 in a closed space or an SMIF (standard mechanical interface) pod.

The interface IF has a function of receiving the substrate 90 coated with the resist from the transport robot TR and transferring the same to the exposure unit SP while receiving the exposed substrate 90 and transferring the same to the transport robot TR. The interface IF also has a function of temporarily stocking the substrate 90 before and after exposure in order to adjust the timing for transferring the substrate 90 between the same and the exposure unit SP, and comprises a robot (not shown) transferring the substrate 90 between the same and the transport robot TR and a buffer cassette (not shown) receiving the substrate 90.

The coating unit SC is the so-called spin coater dropping photoresist on the main surface of the substrate 90 while rotating the same thereby homogeneously coating the substrate 90 with the photoresist. The exposure unit SP is the so-called stepper exposing the substrate 90 through a mask pattern. The developing unit SD is the so-called spin developer developing the exposed substrate 90 by supplying a developer onto the same.

The CD measuring unit 10 has the function of a scanning electron microscope (SEM). This CD measuring unit 10 scans the surface of the developed substrate 90 with an electron beam thereby measuring the line width (defining the line width of a circuit after etching: hereinafter simply referred to as “line width”) of a resist film formed by the development and inspects whether or not a desired line width is obtained. In other words, the CD measuring unit 10 corresponds to the inspection unit in the present invention. The method of measuring the line width with the CD measuring unit 10 is not restricted to the above but the CD measuring unit 10 may alternatively employ an optical method, for example.

The respective units SC, SD, SS 10 and 11 form an integrated arrangement contained in a single housing HS covering the respective units. The robot TR is also contained in the single housing HS and associated with the integrated arrangement. The coating unit SC, the developing unit SD included in the integrated arrangement and the exposure unit SP connected to the interface IF are used in the process for forming a material pattern layer (e.g., a resist pattern layer) on the substrate 90. The process includes: the step of forming a uniform material layer (resist layer) by the coating unit SC; the step of selectively activating the material layer by the exposure unit SP, and the step of developing parts of material pattern layer by the developing unit SD. The spin scrubber unit SS or the cleaning unit is effective to clean the surface of the substrate.

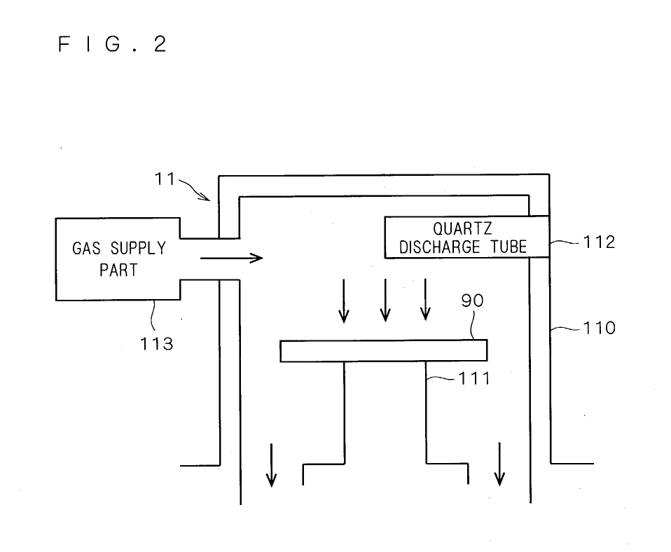

FIG. 2 conceptually illustrates the asher unit 11 in the substrate processing apparatus 1 according to the first preferred embodiment. The asher unit 1 comprises a chamber 110, a chuck 111 holding the substrate 90, a quartz discharge tube 112 discharging a microwave and a gas supply part 113 supplying gas into the chamber 110.

The asher unit 11, having the function of a general plasma ashing apparatus, has a function of removing the resist film formed on the substrate 90 thereby regenerating the substrate 90 in a state reprocessible in the substrate processing apparatus 1. In other words, the asher unit 11 mainly corresponds to the regenerative processing unit in the present invention. The substrate 90 regenerated by the regenerative processing unit is hereinafter referred to as a regenerated substrate 91.

The cleaning unit SS cleans the substrate 90 while rotating the same by spin chucking and supplying a detergent to the main surface thereof. The cleaning unit SS may further have a function of cleaning the main surface of the substrate 90 with a brush or a function of cleaning the back surface of the substrate 90.

The substrate processing apparatus 1 is properly provided with a heating unit (hot plate: not shown) heating the substrate 90 to a prescribed temperature, a cooling unit (cooling plate: not shown) cooling the heated substrate 90 to a prescribed temperature, a filter fun unit (not shown) forming a down flow of clean air controlled in temperature and relative humidity with respect to a prescribed space and the like.

Processing of the substrate 90 in the substrate processing apparatus 1 is now described. In the substrate processing apparatus 1, the transport robot TR first receives the substrate 90 from the indexer IND and transfers the same to the coating unit SC.

The coating unit SC coats the surface of the substrate 90 with the resist by the so-called spin coating of discharging the resist and coating the substrate 90 with the same while rotating and holding the substrate 90.

The transport robot TR discharges the substrate 90 coated with the resist from the coating unit SC and transfers the same to the exposure unit SP through the interface IF. The exposure unit SP exposes the surface of the substrate 90 coated with the resist, which is a photosensitive material, while repetitively stepping or scanning the same through the mask pattern.

The transport robot TR transfers the substrate 90 exposed in the exposure unit SP to the developing unit SD through the interface IF. The developing unit SD discharges the developer to the substrate 90 exposed with a prescribed circuit thereby developing the substrate 90.

The transport robot TR discharges the developed substrate 90 from the developing unit SD and transfers the same to the CD measuring unit 10. The CD measuring unit 10 measures the line width of the substrate 90 and compares the same with a prescribed value previously set as a proper value, thereby detecting abnormality of the substrate 90.

When the line width measured by the CD measuring unit 10 deviates from the prescribed value and the substrate 90 is determined as abnormal, the transport robot TR transfers the substrate 90 to the asher unit 11.

The asher unit 11 discharges the microwave from the quartz discharge tube 112 with respect to the gas supplied from the gas supply part 13 thereby generating a plasma (e.g., an oxygen plasma) of reactive gas. A power source (not shown) supplies power to the quartz discharge tube 112.

The asher unit 11 holds the substrate 90 coated with the resist by the chuck 111 provided in the chamber 110 while diffusing the generated plasma onto the held substrate 90 by a method such as a downstream system, for example, thereby chemically reacting the resist applied to the surface of the substrate 90 and the plasma with each other.

The resist, which is an organic compound consisting of carbon, oxygen and hydrogen, reacts with the plasma to form gas (carbon dioxide, oxygen and steam when oxygen plasma is employed), which in turn is removed from the surface of the substrate 90. The generated gas is exhausted from the bottom of the asher unit 11, as shown in FIG. 2. The method of ashing is not restricted to the above but a method of chemically reacting the resist with high-concentration ozone may alternatively be employed, for example.

Thus, the asher unit 11 processes the substrate 90 requiring regenerative processing so that the substrate processing apparatus 1 can perform the regenerative processing therein, whereby the substrate 90 inspectingly detected as defective may not be transferred between areas but efficiency of the regenerative processing can be improved.

The asher unit 11 converts the resist to the gas by the chemical reaction in the regenerative processing and removes the same. However, part of the resist to be removed may remain on the surface of the substrate 90 as particles due to popping or the like, and the particles must be sufficiently removed. Therefore, the transport robot TR transfers the regenerated substrate 91 to the cleaning unit SS for cleaning the same.

Thus, particles or contaminants adhering to the regenerated substrate 91 due to the regenerative processing can be so removed that the regenerated substrate 91 can be efficiently reused.

The transport robot TR transfers the cleaned regenerated substrate 91 to the indexer IND, which in turn stores the same in the carrier as the unprocessed substrate 90. Thereafter the indexer IND takes out the regenerated substrate 91 again so that the substrate processing apparatus 1 starts processing the same.

On the other hand, the transport robot TR transfers the substrate 90 (or the regenerated substrate 91) determined as normal in the inspection by the CD measuring unit 10 to the indexer IND, which in turn returns the same to a prescribed carrier for terminating the processing in the substrate processing apparatus 1. In other words, the substrate processing apparatus 1 repeats prescribed processing on the substrate 90 until the substrate 90 is determined as normal through the inspection by the CD measuring unit 10.

Thus, the substrate processing apparatus 1 can prevent the carrier from a sparse state by repeating the processing until the substrate 90 is normally processed while no interruption lot may be fed for the regenerative substrate 91, whereby a burden for managing the substrate 90 can be reduced.

The substrate processing apparatus 1 not only regenerates the substrate 90 when the CD measuring unit 10 determines that the line width thereof deviates from the prescribed range but also determines that the cause for the defect is defocusing or deviation of the exposure of the exposure unit SP and corrects the exposure unit SP in response to this cause.

Thus, the substrate processing apparatus 1 can automatically eliminate the cause for the defect by changing control with respect to the exposure unit SP in response to the result of the inspection by the CD measuring unit 10, thereby preventing occurrence of a further defective substrate. When the substrate 90 is already exposed before the exposure of the exposure unit SP is corrected on the basis of the result of the inspection by the CD measuring unit 10, the substrate processing apparatus 1 performs a similar inspection and regenerative processing also on this substrate 90. In this case, the substrate processing apparatus 1 does not corrects the exposure of the exposure unit SP in order to prevent redundant correction of the exposure.

As hereinabove described, the asher unit 11 performs the regenerative processing so that the substrate processing apparatus 1 may not transfer the substrate 90 detected as defective between areas and causes no sparseness of the carrier or no interruption lot, whereby the efficiency of the regenerative processing on the substrate 90 can be improved.

The substrate processing apparatus 1 performs the inspection by the CD measuring unit 10 therein, whereby no inspection step may be separately performed after the processing.

Further, the substrate processing apparatus 1 can automatically perform proper processing such as regenerative processing and removal of the cause for the defect without requiring operator's determination by changing control with respect to the substrate 90, each processing unit and the transport robot TR in response to the result of the inspection of the CD measuring unit 10.

While the substrate processing apparatus 1 according to the first preferred embodiment performs the regenerative processing and changes the control in response to the result of the inspection of the line width of the developed substrate 90 by CD measurement, the inspection of the substrate 90 is not restricted to the CD measurement inspection. For example, the substrate processing apparatus 1 may alternatively be provided with a unit inspecting the state of the resist coated in the coating unit SC by a macro inspection as an inspection unit. Further, the inspection by the inspection unit is not restrictively performed after the substrate processing apparatus 1 terminates the processing but is desirably performed in a proper processing stage in response to the contents of the inspection. In addition, the regenerative processing for removing the resist film is not restricted to a dry method by ashing.

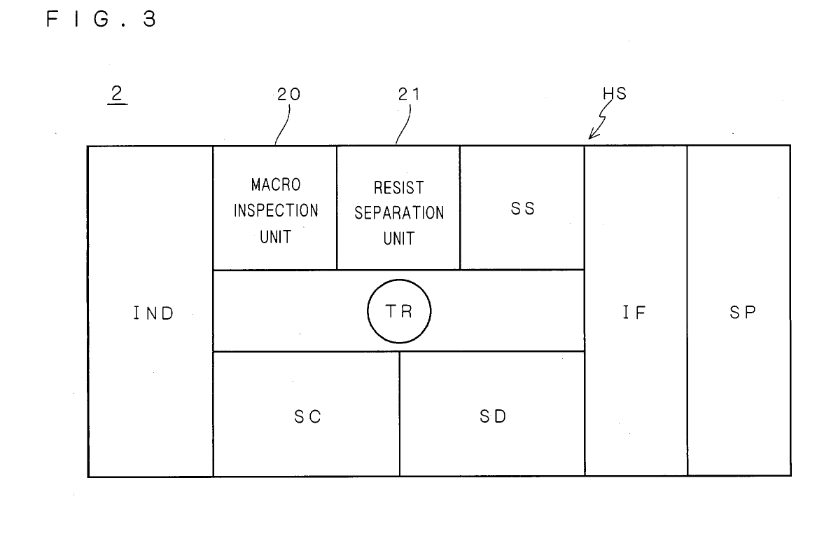

FIG. 3 is a schematic plan view showing the structure of a substrate processing apparatus 2 according to a second preferred embodiment of the present invention formed on the basis of the aforementioned principle. The substrate processing apparatus 2 comprises a macro inspection unit 20 and a resist separation unit 21 as an inspection unit and a regenerative processing unit respectively. Other portions of the substrate processing apparatus 2 similar to those of the substrate processing apparatus 1 are properly denoted by the same reference numerals, and redundant description is omitted.

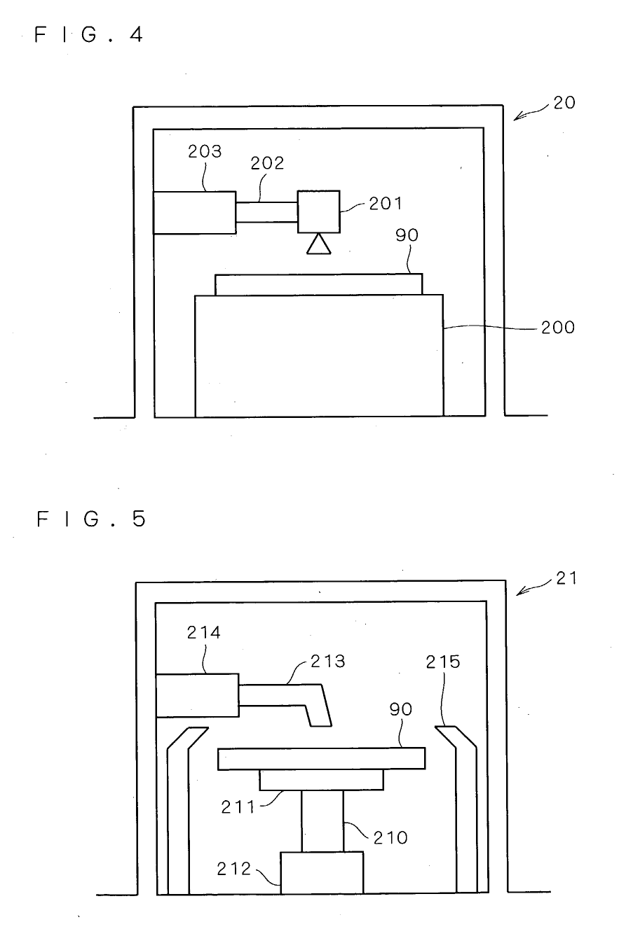

FIG. 4 is a side elevational view showing the structure of the macro inspection unit 20. The macro inspection unit 20 comprises a stage 200 receiving a substrate 90 on a prescribed position, a two-dimensional CCD camera (hereinafter simply referred to as “camera”) 201, a camera support member 202 and a camera moving part 203 for moving the camera 201 to a prescribed position with respect to the substrate 90. The macro inspection unit 20 images the surface of the substrate 90 with the camera 201 and performs image recognition on image data obtained by this imaging thereby inspecting a resist coating state and detecting abnormality of a resist film formed on the substrate 90.

FIG. 5 is a side elevational view showing the structure of the resist separation unit 21. The resist separation unit 21 comprises a support shaft 210, a spin chuck 211 holding the substrate 90, a spin motor 212 generating driving force for rotating the spin chuck 211 through the support shaft 210, a nozzle 213 discharging a remover solution such as a thinner dissolving the resist, a nozzle driving part 214 moving the nozzle 213 to a prescribed position and a cup 215. The resist separation unit 21 discharges the remover solution to the surface of the substrate 90 coated with the resist thereby removing the resist film formed on the substrate 90.

In the substrate processing apparatus 2, a transport robot TR first receives the substrate 90 from an indexer IND and transfers the same to a coating unit SC. The coating unit SC coats the surface of the substrate 90 with the resist, similarly to the coating unit SC in the substrate processing apparatus 1 according to the first preferred embodiment.

Then, the transport robot TR discharges the substrate 90 coated with the resist from the coating unit SC and transfers the same to the macro inspection unit 20.

Thus, when inspecting the resist coating state, the substrate processing apparatus 2 can remove waste processing in a subsequent step by performing an inspection before transferring the substrate 90 coated with the resist to the subsequent step such as an exposure step or a development step and sifting out a defective substrate 90.

In the macro inspection unit 20, the stage 200 holds the transferred substrate 90 on a prescribed position. Then, the camera moving part 203 successively moves the camera 201 to prescribed positions so that the camera 201 images the surface of the substrate 90 and transfers the image data to a determination part (not shown).

Then, the determination part performs image recognition on the image data obtained by imaging the surface of the substrate 90 and detects irregular resist coating on the substrate 90 thereby determining the resist coating state. Such image processing and determination processing can be performed by determining distribution of brightness of photoreceptive data of each pixel through the fact that a portion coated with the resist is relatively dark and a thin spot portion or a thin portion of the resist is relatively bright, for example. While the camera 201 is moved to dividedly image the surface of the substrate 90 in the second preferred embodiment, the substrate processing apparatus 2 may alternatively image the overall surface of the substrate 90 at once with a camera 201 having a relatively wide imaging range.

The transport robot TR transfers the substrate 90 determined as abnormal in the inspection by the macro inspection unit 20 to the resist separation unit 21.

In the resist separation unit 21, the spin chuck 211 provided on the support shaft 210 holds the substrate 90 on the prescribed position. Then, the spin motor 212 generates the driving force and rotates the spin chuck 211 thereby rotating the substrate 90.

Then, the nozzle driving part 214 moves the nozzle 213 to the prescribed position so that the nozzle 213 discharges the remover solution to the surface of the rotated/held substrate 90 thereby dissolving the resist film formed thereon. The dissolved resist film is removed from the surface of the substrate 90 due to the turning force. This processing is performed in the cup 215, so that the removed resist film is not scattered in the resist separation unit 21.

Thus, the substrate processing apparatus 2 can regenerate the substrate 90 causing irregular resist coating or the like to a reprocessible state therein.

The transport robot TR transfers a regenerated substrate 91 resulting from removal of the resist film by the resist separation unit 21 to the indexer IND after cleaning by the cleaning unit SS, so that the indexer IND stores the same in a carrier as an unprocessed substrate. Thereafter the indexer IND transfers the regenerated substrate 91 to the transport robot TR, which in turn transfers the same to a coating unit SC so that the substrate processing apparatus 2 starts processing.

The transport robot TR transfers the substrate 90 (or the regenerated substrate 91) determined as normally coated in the inspection by the macro inspection unit 20 to an exposure unit SP, which in turn exposes the substrate 90 (or the regenerated substrate 91). The substrate 90 (or the regenerated substrate 91) is further transferred to a developing unit SD to be developed, transferred to the indexer IND and stored in the carrier as a processed substrate, so that the substrate processing apparatus 2 terminates the processing.

When the macro inspection unit 20 detects abnormality, the substrate processing apparatus 2 performs the following operation in response to the state of the abnormality:

When the substrate 90 is homogeneously coated with the resist with an abnormal thickness, the substrate processing apparatus 2 adjusts the rotational speed of the coating unit SC. In other words, the substrate processing apparatus 2 increases the rotational speed if the thickness is too large, while decreasing the rotational speed when the thickness is too small.

Thus, the substrate processing apparatus 2 can also change control with respect to each processing unit in response to the result of the inspection of the macro inspection unit 20 similarly to the substrate processing apparatus 1, thereby preventing occurrence of a further defective substrate 90.

When the resist is irregular or blurred, the substrate processing apparatus 2 determines defective discharge resulting from a dry nozzle or an insufficient resist solution and displays a warning on a display part such as a display (not shown) if manual restoration is necessary, for stopping the processing with the coating unit SC. The substrate processing apparatus 2 performs the inspection with the macro inspection unit 20 on the substrate 90 already coated with the resist for transferring the substrate 90 to the resist separation unit 21 if abnormality is detected while transferring the normal substrate 90 to the exposure unit SP. When an operator completely restores the defective discharge, the substrate processing apparatus 2 takes out the substrate 90 from the carrier storing unprocessed substrates and starts processing.

Thus, also when the cause for the defective substrate 90 cannot be automatically restored, the substrate processing apparatus 2 can properly cope with the defective substrate 90 by changing control in response to the result of the inspection by the macro inspection unit 20.

Thus, the substrate processing apparatus 2 according to the second preferred embodiment can also perform resist separation (regeneration) therein similarly to the substrate processing apparatus 1 according to the first preferred embodiment, whereby the regenerated substrate 91 may not be transferred between areas but the substrate processing apparatus 2 can attain an effect similar to that of the substrate processing apparatus 1. While the asher unit 11 according to the first preferred embodiment may be employed in place of the resist separation unit 21 as the regenerative processing unit for removing the resist film for attaining a similar effect, either regenerative processing unit is preferably properly selected in response to a method of subsequent etching or the like.

The inspection unit is not restricted to the CD measuring unit 10 or the macro inspection unit 20 but may alternatively be implemented by any unit having the function of a film thickness measuring apparatus inspecting the resist coating state by measuring the thickness of a resist film or an overlay inspection apparatus inspecting an overlay state of formed layers so far as the same performs an inspection as to prescribed processing in the substrate processing apparatus 1 or 2. Further, the substrate processing apparatus 1 or 2 may be provided with a plurality of such inspection units.

Further, each inspection unit may not necessarily inspect only one item. In the second preferred embodiment, for example, the macro inspection unit 20 may detect not only the resist coating state but also defocusing of the exposure unit SP. In this case, the substrate processing apparatus 2 cleans the back surface of the substrate 90 after resist separation and surface cleaning, in order to remove particles from the back surface.

The inspection unit 10 or 20 may not be present as a single unit in the substrate processing apparatus 1 or 2 but the substrate processing apparatus 1 or 2 may have the inspection unit 10 or 20. More specifically, the inspection unit 10 or 20 may be provided in the indexer IND or a space on a transfer path scanned by the transport robot TR in the substrate processing apparatus 1 or 2, for example.

The resist separation unit 21 in the substrate processing apparatus 2 according to the second preferred embodiment may comprise a nozzle for discharging a detergent and a cleaning brush independently of the nozzle 213. In this case, the resist separation unit 21 can clean the substrate 90 and hence no cleaning unit SS may be separately provided but the footprint of the substrate processing apparatus 2 can be removed.

The structure of the substrate processing apparatus 1 or 2 is not restricted to that of each of the aforementioned preferred embodiments. For example, a partial structure of the exposure unit SP or the like may alternatively be provided as an external device, and the substrate processing apparatus 1 or 2 may properly display information as to correction of the exposure or the like in this case so that the operator corrects the exposure on the basis of the displayed information.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus comprising:
a plurality of processing units, each executing prescribed processing on a substrate, including a regenerative processing unit regenerating said substrate; and
a transport mechanism transporting said substrate between said plurality of processing units,
said plurality of processing units and said transport mechanism being integrated with each other.

2. The substrate processing apparatus according to claim 1, further comprising an inspection unit performing an inspection of said substrate.

3. The substrate processing apparatus according to claim 2, further comprising an element deciding processing on said substrate in response to a result of said inspection by said inspection unit.

4. The substrate processing apparatus according to claim 2, further comprising an element changing control on said processing units in response to a result of said inspection by said inspection unit.

5. The substrate processing apparatus according to claim 1, wherein
said plurality of processing units include a cleaning unit cleaning said substrate.

6. An apparatus for processing a substrate, comprising:
a) an integrated arrangement, comprising
a-1) process units for forming a material pattern layer on a substrate,
a-2) an inspecting unit for inspecting said material pattern layer on said substrate to detect a defect in said material pattern layer, and
a-3) a removing unit for removing said material pattern layer from said substrate to refresh said substrate; and
b) a transfer robot associated with said integrated arrangement and operable to transfer said substrate between respective units included in said integrated arrangement,
wherein said robot transports said substrate from said inspecting unit to said removing unit when defect is found in said material pattern layer.

7. The apparatus according to claim 6, wherein
said removing unit includes an asher unit for converting said material pattern layer on said substrate into ash.

8. The apparatus according to claim 7, wherein
said integrated arrangement further comprising
a-5) a cleaning unit for cleaning said substrate, and
said robot is operable to transfer said substrate from said removing unit to said cleaning unit when said material pattern layer of said substrate is defective.
